(19) United States
(12) Patent Application Publication
(10) Pub. No.: US 2009/0186980 A1
(43) Pub. Date: Jul. 23, 2009

(54) MANUFACTURING METHOD OF LOW-K THIN FILMS AND LOW-K THIN FILMS MANUFACTURED THEREFROM

(76) Inventors: Dong-Geun Jung, Seoul (KR); Jae-Young Yang, Gyeonggi-do (KR); Sung-Woo Lee, Gyeonggi-do (KR)

Correspondence Address: NEAL, GERBER, & EISENBERG, SUITE 1700, 2 NORTH LASALLE STREET, CHICAGO, IL, 60602, US

(21) Appl. No.: 12/301,614

(22) PCT Filed: Jun. 27, 2007
(86) PCT No.: PCT/KR07/03107

§ 371 Date: Nov. 19, 2008

(30) Foreign Application Priority Data
Mar. 27, 2007 (KR) 10-2007-0029594

(51) Int. Cl. C08L 83/04; C23C 16/513

(52) U.S. Cl. 524/588; 427/489

(57) ABSTRACT

The present invention relates to a method of manufacturing a low-k thin film and the low-k thin film manufactured therefrom. More specifically, the method of manufacturing a low-k thin film in accordance with an embodiment of the present invention includes subjecting thin film, which is formed by plasma polymerization, to post-heat treatment using an RTA device, and low-k thin film manufactured therefrom.

A method of manufacturing a low-k thin film in accordance with an embodiment of the present invention includes: evaporating a precursor solution including decamethylcyclopentasiloxane and cyclohexane in a bubbler; inflowing the evaporated precursor from the bubbler to a plasma deposition reactor; depositing a plasma-polymerized thin film on a substrate in the reactor by using a plasma in the reactor; and post-heat-treating by an RTA device.

### CROSS REFERENCE TO RELATED APPLICATION

The present Non-Provisional Patent Application is a national stage continuation application of International Application No. PCT/KR2007/003107, filed on 27 Jun. 2008, which claims priority to Korean Patent Application No. 10-2007-0029594, filed on 27 Mar. 2008, both of which are incorporated herein by reference.

### TECHNICAL FIELD

The present invention relates to a method of manufacturing a low-k thin film and the low-k thin film manufactured therefrom. More specifically, the present invention relates to a low-k thin film manufacturing method comprising subjecting a thin film which is formed by plasma polymerization to post-heat treatment using an RTA device, and the low-k thin film manufactured therefrom.

### BACKGROUND OF THE INVENTION

These days, one of the major steps in manufacturing semiconductor devices involves forming metal and dielectric thin films on a substrate by a gaseous chemical reaction. The said thin film deposition process is called chemical vapor deposition or CVD. In an ordinary thermal CVD process, a reactive gas is provided to a surface of a substrate so that thermally induced chemical reactions occur on the surface of the substrate, and a predetermined thin film is formed as a result. High temperature at which a predetermined thermal CVD process performs can cause damages to the structure of the device which has a film formed on the surface of the substrate. A preferable method depositing metal and dielectric thin film at relatively low temperature is Plasma-enhanced CVD (PECVD) described in U.S. Pat. No. 5,362,526 (“Plasma-enhanced CVD process using TEOS for depositing silicon oxide”) which is incorporated by reference herein.

The plasma-enhanced CVD technique facilitates excitation and/or dissociation of a reactive gas by applying radio frequency (RF) energy to a reaction zone so as to form plasma of high-reactive species. High reactiveness of the free-species reduces energy required for causing chemical reaction, which makes temperature required for the PECVD process lower. The size of semiconductor device structure has become significantly decreased by introduction of said device and process.

Also, in order to reduce the resistive capacitive delay (RC delay) of a multilayer metal film used in an integrated circuit of a ultra large-scale integrated (ULSI) semiconductor device, researches for forming interlayer dielectric used in metal wiring with materials having low-k (k≦2.4) have been actively carried out these days. Said low dielectric film can also be formed with organic materials or inorganic materials, such as a Fluorine (F)-doped oxide (SiO₂) layer and an F-doped amorphous carbon (a-C:F) layer. Polymeric thin film having relatively low-k and high thermal stability is generally used for organic materials.

Silicon dioxide (SiO₂) or silicon oxyfluoride (SiOF), which have been mainly used as interlayer dielectric till lately, have the problems of high capacitance, long RC delay, etc., when manufacturing ultra large-scale integrated circuits of no more than 0.5 μm. Recently, researches for substituting these materials with new low dielectric materials have been actively carried out. However, no concrete solution has been proposed.

For example, the low-dielectric materials considered as substitution materials for SiO₂ at the present time include BCB (benzocyclobutene), SiLK™ (from Dow Chemical Company), FLARE (fluorinated poly(arylene ether), from Allied Signals) and organic polymers, such as polyimide, which are mainly used in spin coating; Black Diamond™ (from Applied Materials), Coral™ (from Novellus), SiOF, alkyl silane and parylene, which are mainly used in chemical vapor deposition (CVD); and porous thin film materials such as xerogel or aerogel.

Most of the polymeric thin films are formed by a spin casting process, which comprises chemically synthesizing a polymer; spin coating the polymer on a substrate; and curing the polymer. Since pores having a size of several nm are formed in the film of low-k materials made by such process, the density of the thin film is reduced to form low-k materials. Usually, the organic polymers deposited by spin coating have merits of generally low dielectric constant (k) and superior planarization. However, they are unsuitable for the applications since the upper limit of heat-resisting is lower than 450° C. so that the thermal stability is poor, and also, they have various difficulties in manufacturing devices since the size of pores is so large that the pores are not uniformly distributed in the film. Additionally, they have other problems, including bad adhesion with wiring materials of upper and lower sides, generation of high stress by the organic polymeric thin film-specific thermal curing, and depreciated reliability of the device by alteration of dielectric constant (k) because of adsorption of surrounding water.

### SUMMARY OF THE INVENTION

In order to find solutions for the above-mentioned problems, the present inventors had researched a method for manufacturing low-k thin film, wherein the dielectric constant (k) is greatly lower than the prior art. As a result, they have found in the present invention that a plasma-polymerized polymeric thin film deposited by the PECVD process using cyclic-shaped precursors can form pores not exceeding the size of several nm, and shorten the complicated process and the period of time for pre- and post-treatments in the spin casting process, and also that a novel method can improve a dielectric constant and mechanical properties (e.g., hardness and elastic modulus) of a material by using, for example, post-heat treatments.

Therefore, the technical problem which the present invention is trying to solve is to prepare a plasma-polymerized low-k thin film having considerably low dielectric constant.

Also, another object of the present invention is to provide a process for improving the dielectric constant and mechanical strength.

### TECHNICAL SOLUTION

In order to solve such problems, a thin film, which is employed as interlayer dielectric, for semiconductor devices is used, wherein the thin film is deposited by PECVD using decamethylcyclopentasiloxane (DMCPSO) and cyclohexane as the precursors.

More specifically, the thin film of the invention is prepared by following steps: evaporating decamethylcyclopentasiloxane and cyclohexane contained in each bubbler to make them gas phase; flowing carrier gas into the bubbler; discharging each decamethylcyclopentasiloxane and cyclohexane with carrier gas out of the bubbler and flowing them into a furnace for plasma deposition at the same time; depositing thin film to substrate in the furnace by chemical vapor deposition using plasma of the furnace; and carrying out post-heat treatment.

A better understanding of the objects, advantages, features, properties and relationships of the invention will be obtained from the following detailed description and accompanying drawings which set forth at least one illustrative embodiment and which are indicative of the various ways in which the principles of the invention may be employed.

### BRIEF DESCRIPTION OF DRAWINGS

FIG. 1 is a schematic diagram of a PECVD (Plasma Enhanced Chemical Vapor Deposition) system used for preparation of a low-k thin film for semiconductor devices according to the present invention.

FIG. 2 is a schematic diagram of an RTA (Rapid Thermal annealing) device used for post-heat treatment.

FIG. 3 is a graph illustrating chemical composition of a low dielectric constant (low-k) thin film prepared according to prior art by AES (Auger electron spectroscopy) measurements.

FIG. 4 is a graph illustrating a thermal stability TGA (ThermoGravimetric Analysis) of a low-k thin film prepared according to prior art.

FIG. 5 is a graph illustrating changes in dielectric constant of a thin film by post-heat treatment according to an embodiment of the present invention.

FIG. 6 is a graph illustrating changes in the thickness of a thin film (i.e., Thickness Retention) by post-heat treatment.

FIGS. 7 and 8 are graphs illustrating hardness and elastic modulus of the low-k thin film, which is prepared according to an embodiment of the present invention and is further heat treated, measured by nano-indentor, respectively.

FIG. 9 is a graph illustrating the chemical structure obtained from Fourier transform infrared (FT-IR) spectroscopy of the low-k thin film prepared according to an embodiment of the present invention.

FIG. 10 is a graph illustrating the chemical structure obtained from FT-IR of the low-k thin film which is prepared according to an embodiment of the present invention and is further post-heat treated by using nitrogen gas depending on the temperature of the post-heat treatment.

FIG. 11 is a graph illustrating the chemical structure obtained by FT-IR of the low-k thin film which is further post-heat treated by using oxygen gas.

FIG. 12 is a graph illustrating the chemical structure of hydrocarbon bond obtained from subtracted FT-IR spectrum of the low-k thin film which is prepared according to an embodiment of the present invention and is further heat treated.

FIG. 13 is a graph illustrating the chemical structure of Si—O related bond.

FIGS. 14 and 15 are graphs illustrating the relation between dielectric constant and the chemical structure obtained from the subtracted method for the low-k thin film, which is prepared according to an embodiment of the present invention and is further heat treated.

FIGS. 16 and 17 are graphs illustrating the relation between the dielectric constant and the chemical structure obtained from the subtracted method for the low-k thin film, which is prepared according to an embodiment of the present invention and is further heat treated.

### DETAILED DESCRIPTION

The description that follows describes, illustrates and exemplifies one or more particular embodiments of the present invention in accordance with its principles. This description is not provided to limit the invention to the embodiments described herein, but rather to explain and teach the principles of the invention in such a way to enable one of ordinary skill in the art to understand these principles and, with that understanding, be able to apply them to practice not only the embodiments described herein, but also other embodiments that may come to mind in accordance with these principles. The scope of the present invention is intended to cover all such embodiments that may fall within the scope of the appended claims, either literally or under the doctrine of equivalents.

The method of manufacturing a low-k thin film for semiconductor devices according to an embodiment of the present invention is disclosed in detail below, together with the attached drawings, so that a person with ordinary skill in the art to which the invention pertains can easily replicate the invention.

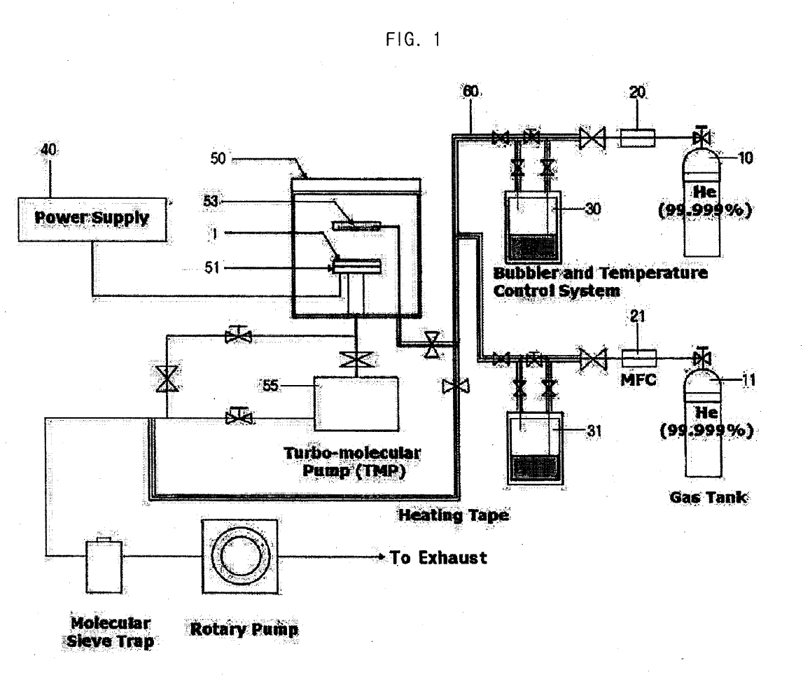

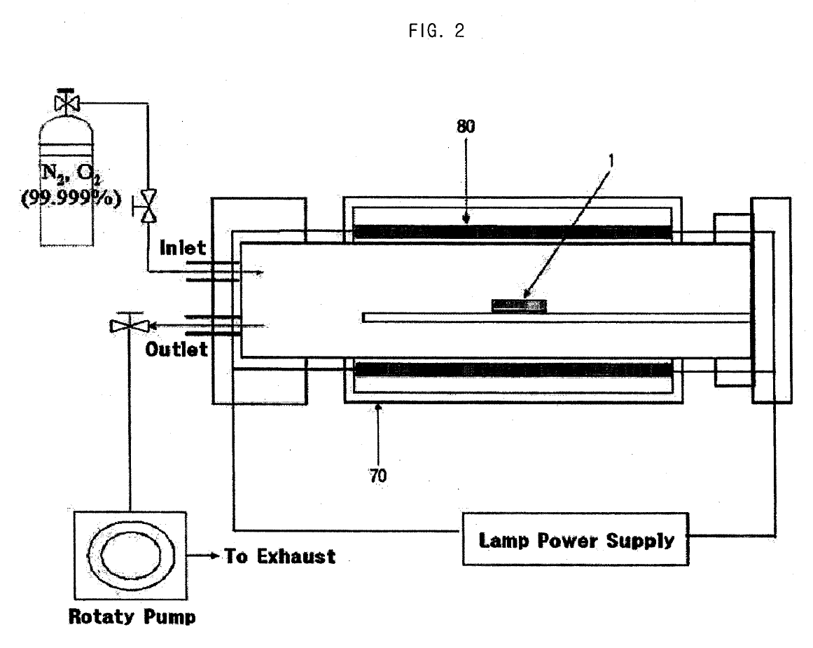

FIG. 1 shows a PECVD system used for preparation of the low-k thin film for semiconductor devices, and FIG. 2 shows an RTA (Rapid Thermal Annealing) device used for post-heat treatment. A thin film-depositing process proceeds through a process chamber consisting of an upper chamber lid and a lower chamber body in the PECVD system using the PECVD method illustrated in FIG. 1. The reaction gas is uniformly sprayed on a substrate placed on the susceptor formed inside of the chamber body through a shower head formed inside of the chamber lid so that the thin film is deposited, wherein the reaction gas is activated by RF (radio frequency) energy which is supplied by an upper electrode comprising a backing plate and the shower head and the lower electrode comprising the susceptor, and thus, the thin film deposition process proceeds. In the post-heat treatment system shown in FIG. 2, a post-heat treatment process rapidly proceeds by heating the substrate up to 550° C. using light from a halogen lamp.

The thin film for semiconductor devices according to an embodiment of the present invention is deposited by the plasma enhanced CVD (PECVD) using decamethylcyclopentasiloxane and cyclohexane as the precursors. The capacitor type of the PECVD system is used in an embodiment of the present invention as shown in FIG. 1. However, in addition to the PECVD system shown in FIG. 1, any type of the PECVD system can be used in the present invention.

The PECVD system used in an embodiment of the present invention includes first and second carrier gas storages 10 and 11 containing carrier gas such as He and Ar; first and second flow control devices 20 and 21 which can control mole of the gas passing through them; first and second bubblers 30 and 31 containing precursors of solid phase or liquid phase; a furnace 50 in which the reaction proceeds; and a radio frequency (RF) generator 40 for generating plasma in said furnace. The carrier gas storages 10 and 11, the flow control devices 20 and 21, the bubblers 30 and 31 and the furnace 50 are connected via transfer tubes 60. The susceptor connected with the RF generator 40 to generate plasma around the susceptor is equipped in the furnace 50, wherein the substrate can be placed on the susceptor. A shower head 53 is supplied with RF power from an RF generator 40 to function as the upper electrode, wherein a shower head extension including ceramics is interposed between the shower head and the chamber lid for insulating with the chamber lid including a metal and preventing leakage of reaction gas. Particularly, the RF power supply supplying energy which is necessary for excitation of the sprayed reaction gas and is connected with the shower head 53 turns the sprayed reaction gas from the shower head 53 into plasma so that a thin film is formed on the substrate. Accordingly, the shower head functions as an upper electrode. A substrate support 51, on which a substrate 1 is disposed is equipped in the furnace. A heater (not shown) is buried in the substrate support so as to heat the substrate 1 disposed on the support 51 to a temperature suitable for the deposition during the thin film deposition process. Also, the substrate support 51 is electrically grounded to function as a lower electrode. An exhaust system is equipped below the chamber body to discharge residual reaction gas in the process chamber after completion of the reaction of the deposition.

The method for depositing thin film using the PECVD system according to the present invention is as follows. Firstly, a substrate 1 made of boron doped silicon (P⁺⁺-Si) having properties of metal is cleaned with trichloroethylene, acetone, methanol, etc., and it is subsequently placed on substrate support 51 of furnace 50. At this time, the basal pressure of the furnace 50 is kept low such as 5×10⁻⁶ Torr or less by pumping of the turbo-molecular pump.

The first and the second bubblers 30 and 31 contain liquid decamethylcyclopentasiloxane and cyclohexane. The first and the second bubblers are heated to 75° C. and 45° C., respectively, to evaporate the precursor solution in the bubblers. The two bubblers are used since two precursors are used in the embodiment. In this case, each one of the precursors, decamethylcyclopentasiloxane and cyclohexane, can be contained in any of the two bubblers. Namely, it is practicable that the first bubbler 30 contains decamethylcyclopentasiloxane as the precursor and the second bubbler 31 contains cyclohexane as the precursor, or contrarily, the first bubbler 30 contains cyclohexane as the precursor and the second bubbler 31 contains decamethylcyclopentasiloxane as the precursor. However, heating temperature of each bubbler should be adjusted to the type of precursor contained in the bubbler.

Each of the carrier gas storages 10 and 11 contains 99.999% ultra-high purity Helium (He) gas used as carrier gas, and the gas flows through transfer tube 60 by the first and the second flow control devices 20 and 21. The carrier gas flowing through said transfer tube 60 flows into the precursor solution in the bubblers 30 and 31 through an inlet tube of the bubblers so as to generate bubbles, and the carrier gas carrying the gaseous precursor flows into transfer tube 60 through an outlet tube of the bubblers.

The carrier gas and gaseous precursor which is passed through the bubblers 30 and 31 and flows through the transfer tube 60 sprays via the head shower 53 of the furnace 50, and at this time, the RF generator 40 connected with the shower head 53 turns the sprayed reaction gas from the shower head 53 into plasma. The plasma precursor sprayed via head shower 53 of the furnace 50 is deposited on the substrate 1 placed on the support 51 to form a thin film. The residual reaction gas after completion of the deposition reaction is discharged by the exhaust system equipped below the chamber body. At this time, the pressure of the furnace 50 is between 10×10⁻¹ Torr and 15×10⁻¹ Torr, and the temperature of the substrate 1 is between 20° C. and 35° C. The temperature of the substrate is controlled by using a heater buried in the substrate support. Also, the power supplied to the RF generator is between 10 W and 20 W, and the generating plasma frequency is about 13.56 MHz.

The thickness of the deposited PPDMCPSO:CHex thin film from the above process measured between 0.4 μm and 0.5 μm. More specifically, the deposition process is as follows. Firstly, mixed monomers transferred into the furnace 50 are activated to reactive species or decomposed by plasma, and thus, condensed on the substrate. Since cross-linking between molecules of decamethylcyclopentasiloxane and cyclohexane is easily accomplished on the said substrate, the PPDMCPSO:CHex thin film deposited under suitable conditions is easily cross-linked by a silicon oxide group and methyl group of decamethylcyclopentasiloxane so that thermal stability is improved and polymerization between the methyl group of decamethylcyclopentasiloxane and cyclohexane is also easily accomplished.

In the present invention, the substrate prepared by the above described process is further subjected to post-heat treatment or annealing using the rapid thermal annealing (RTA) device. The substrate 1 is put into the chamber of the RTA device, and is heated by a number of halogen lamps 80 (wavelength: ˜2 μm), which are equipped in the chamber and generate heat with flame-red light. In the RTA device, the PPDMCPSO:CHex thin film is heat-treated in the temperature range between 300° C. and 600° C. for 1 to 5 minutes in an N₂ and O₂ environment, respectively. The post-heat treatment is carried out at 0.5 to 1.5 atm using the N₂ and O₂ gas, respectively.

A result of the plasma-polymerized thin film set forth above and the thin film which is post-heated to the plasma-polymerized thin film by N₂ or O₂ is confirmed by following experiments. AS-deposited, RTN and RTO in the attached figures are present as follow.

AS-deposited: the early PPDMCPSO:CHex thin film which is plasma-deposited.

RTN: the plasma-deposited PPDMCPSO:CHex thin film which is post-heated by using N₂.

RTO: the plasma-deposited PPDMCPSO:CHex thin film which is post-heated by using O₂.

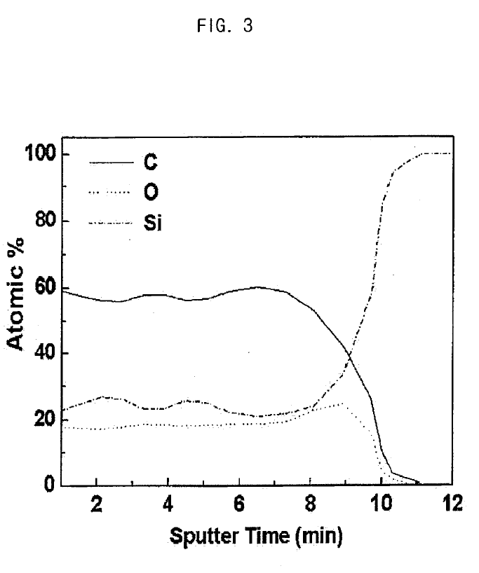

FIG. 3 shows a condition of chemical composition which is measured the plasma-deposited PPDMCPSO:CHex thin film by Auger electron spectroscopy (AES) before the post-heating. The thickness of the measured thin film is 100 nm and the scanning speed of the measured thin film is 10 nm/min. According to the measured result, it can be inferred that the chemical composition ratio of the thin film is silicon:carbon:oxygen=24:57:19 (%), that the composition inside the thin film is uniform, and that there are more carbon than other elements inside the thin film.

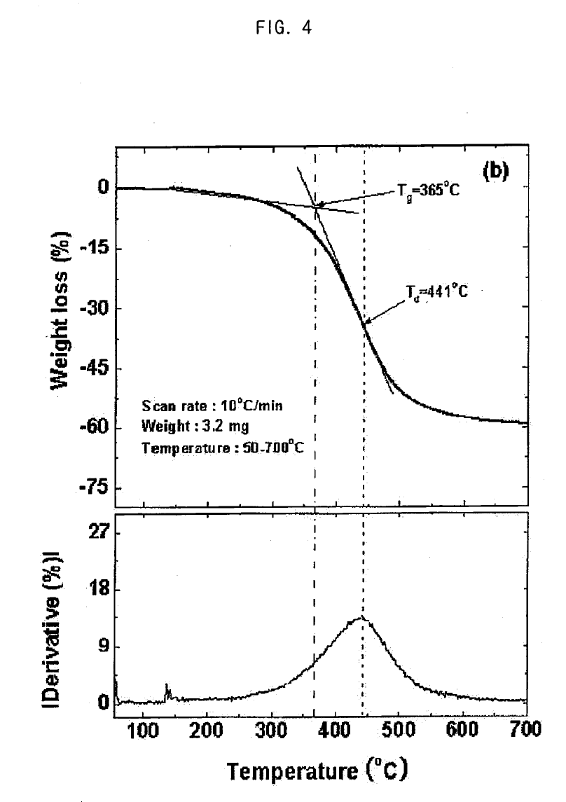

FIG. 4 is a graph showing thermal stability against the plasma-deposited PPDMCPSO:CHex thin film before the post-heating. The thermal scanning speed was 10° C./min and N₂ was used; the mass of the measured thin film was 3.2 mg; and the measurement section was between 50° C. and 700° C. The temperature at which the mass was sharply decreased (glass transition temperature: Tg) was 365° C. and the temperature at which the mass was almost decomposed (glass decomposition temperature: Td) was 441° C.

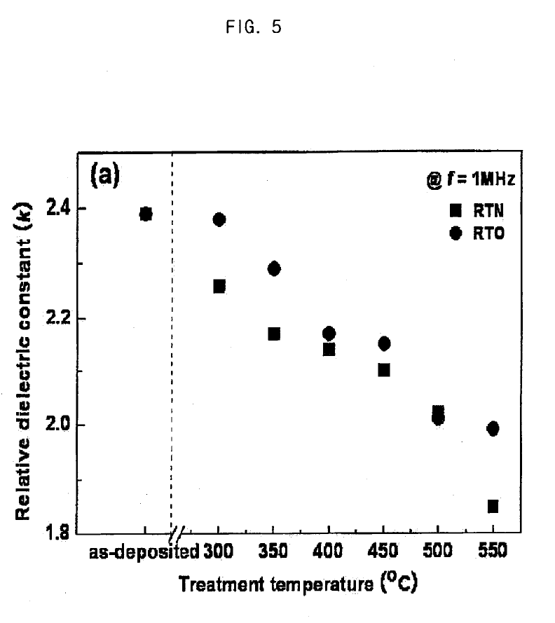

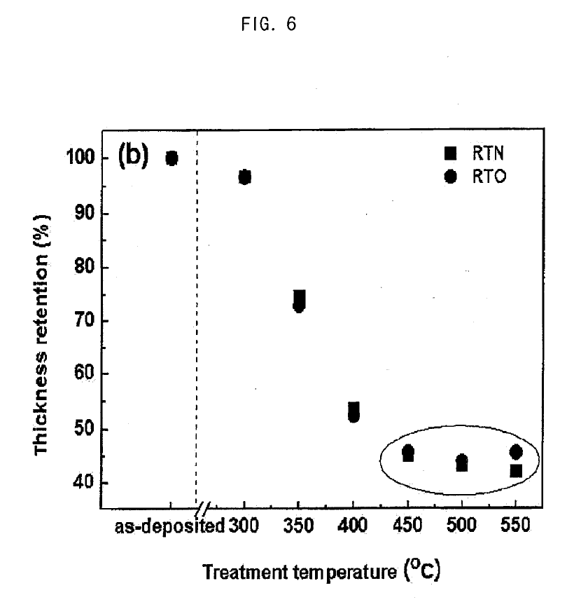

FIG. 5 and FIG. 6 show a relative dielectric constant and a variation of thickness of the thin film, respectively, in which the plasma-deposited PPDMCPSO:CHex thin film was heat-treated by 550° C. using N₂ and O₂. Measurement of the relative dielectric constant was achieved by supplying a 1-MHz frequency signal on the silicon substrate, which has low resistance, by making an electric condenser having Al/PPDMCPSO:CHex/metallic-Si structure. After post-heat treating the plasma-deposited PPDMCPSO:CHex thin film by 550° C. using N₂, when a dielectric constant of the thin film was measured, the dielectric constant was remarkably decreased, from 2.4 to 1.85, and the post-heated thin film by using O₂ (RTO) showed that the dielectric constant of the thin film was decreased, compare to the post-heated thin film using N₂ (RTN), from 2.4 to 1.98. The higher temperature increases, the less the thickness decreases in a variation of thickness of the thin film. Particularly, 48% of sharp variation of thickness was shown at between 350° C. and 400° C. It was in accordance that, comparing to the above shown thermal stability data, no variation of thickness was shown at above 450° C. and no more mass decreasing was shown at above 441° C. Also, according to the experimental result, the variation of thickness was 0.5% or below, and there was almost no change below 300° C.

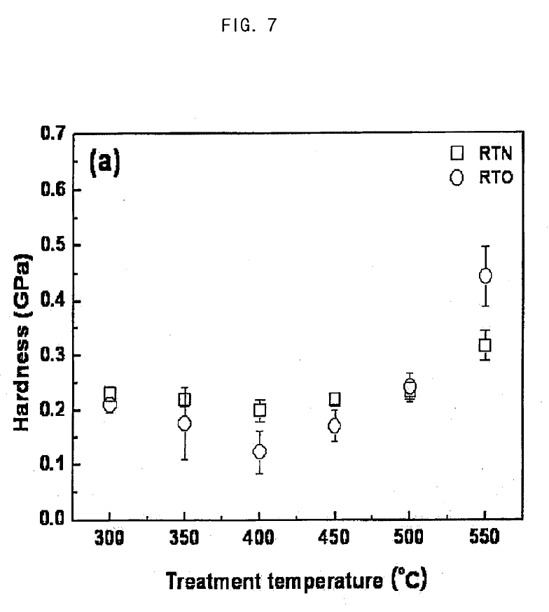

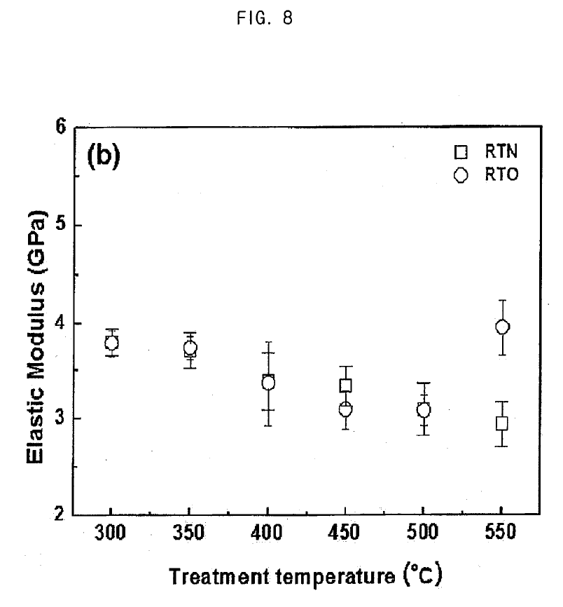

FIGS. 7 and 8 illustrate hardness and elastic modulus of the thin film, measured by a nano-indentor, in which the PPDMCPSO:CHex thin film, which is polymerized by a plasma-enhanced CVD (PECVD) process by using cyclopentasiloxane and cyclohexae precursors, was heat-treated. In the case of the heated thin film by using O₂ (RTO), the hardness was decreased to 0.12 GPa while the temperature went up to 400° C. and the hardness was sharply increased to 0.44 GPa at above 450° C. However, in the case of the heated thin film by using N₂ (RTN), the hardness was slightly decreased to 0.3 GPa at above 450° C. The elastic modulus had a tendency of decrease along with increase of heat-treatment temperature, in RTN and RTO, when the heat-treatment temperature was 550° C., the elastic modulus was slightly increased in RTO.

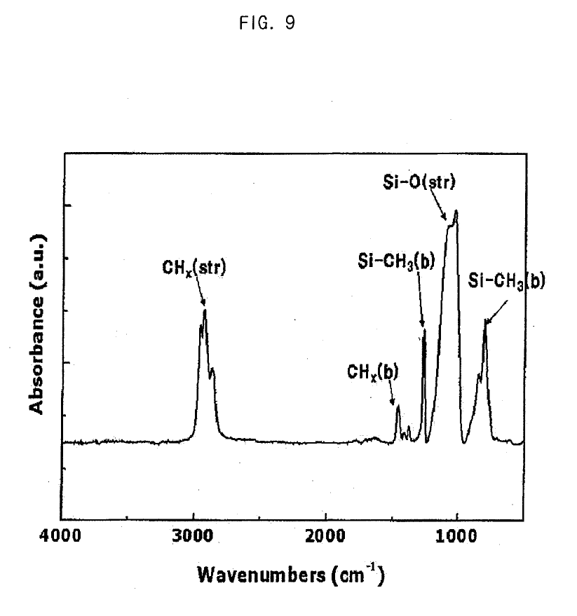

FIGS. 9, 10 and 11 are graphs illustrating the chemical structure of the thin film which is manufactured according to an embodiment of the present invention by Fourier transform infrared (FT-IR) spectroscopy. A horizontal axis illustrates wavenumber, cm⁻¹ and a vertical axis illustrates normalized absorbance. FIGS. 9, 10 and 11 show wave type generated in an overall range. According to FIGS. 9, 10 and 11, it shows that the PPDMCPSO:CHex thin film is polymerized by plasma-enhanced CVD process by using cyclopentasiloxane and cyclohexane precursors, and the post-heat-treated RTN and RTO generate stretching and bending of each chemical structure at the same position over the whole wavenumber range.

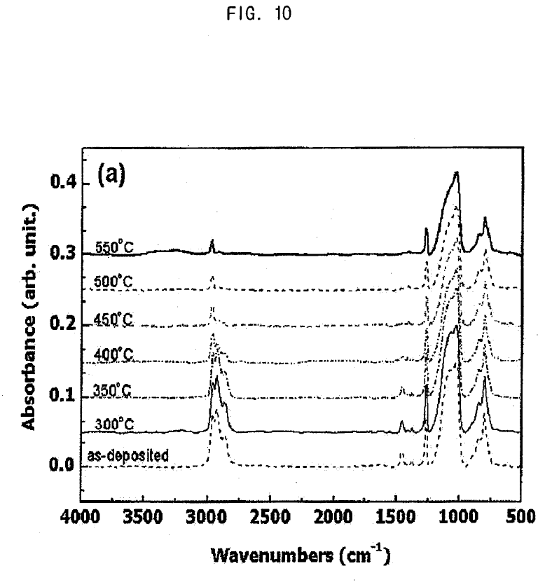

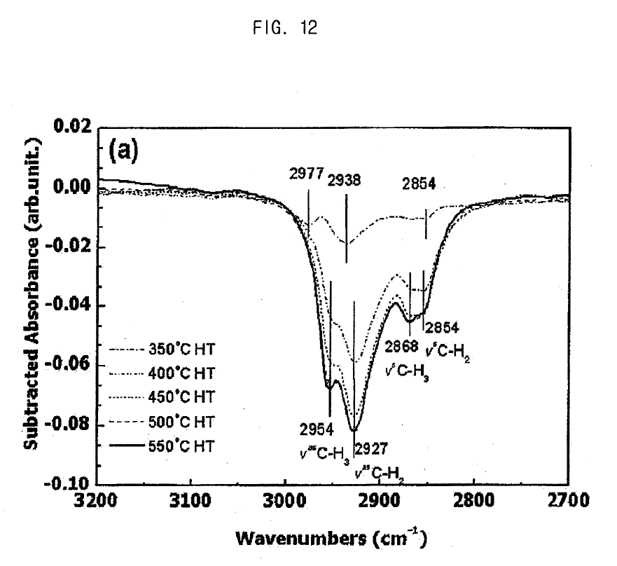

FIG. 12 illustrates normalized absorbance of hydrocarbon, which belongs to an organic matter, among over the whole wavenumber range in FIG. 10. In accordance with FIG. 10, the PPDMCPSO:CHex thin film is polymerized by plasma-enhanced CVD process by using cyclopentasiloxane and cyclohexane precursors, and the post-heat-treated PPDMCPSO:CHex thin film by using nitrogen gas shows a decreasing absorbance temperature. Looking further into the normalized absorbance of hydrocarbon (CHₓ), a methyl group and a ethyl group were shown while more ethyl group was disappeared than the methyl group. Because the methyl group was a form of silicon-carbon, which is the basic bonding, little disappearance was shown after the post-heat treatment. This is because the ethyl group is formed from mixed polymerized cyclohexane bonds as a form of polymer such as ethyl-ethyl-ethyl-(—CH₂—CH₂—CH₂—) in an inner thin film as liable species, and the ethyl group is easily sublimed after the post-heat treatment.

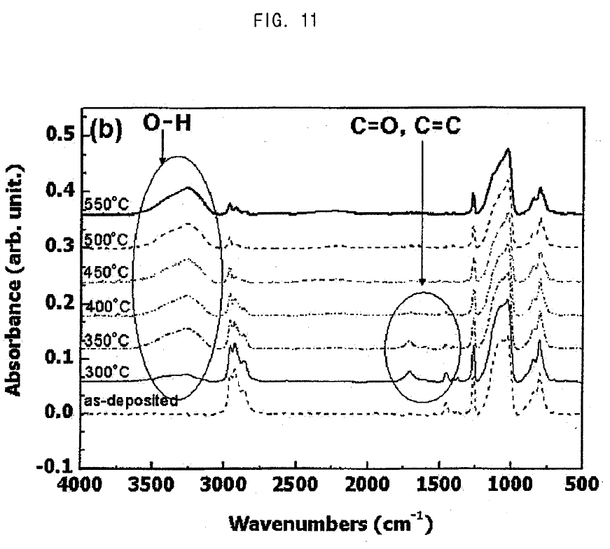

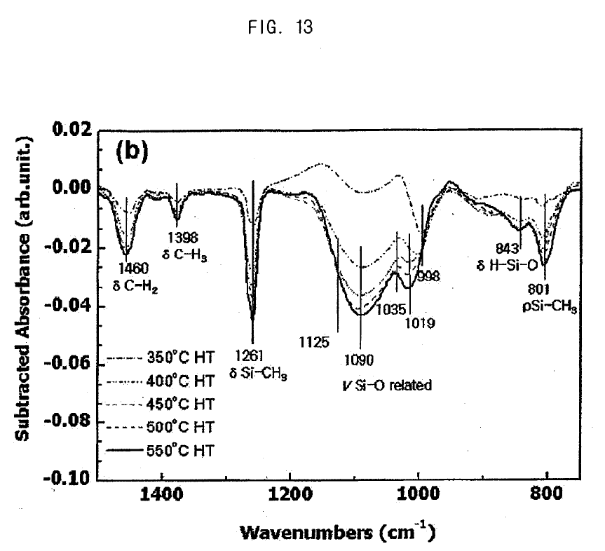

FIG. 13 illustrates normalized absorbance of a bond structure relating to silicon among over the whole wavenumber range in FIG. 11 and is about chemical bond of carbon-silicon oxide (C—SiO), oxygen-silicon oxide (O—SiO) and silicon-methyl (Si—CH₃). The silicon-related bond structure, which is the backbone of the PPDMCPSO:CHex thin film, shows slight variation after the heat treatment.

It is inferred from this phenomenon that heat is penetrated into the PPDMCPSO:CHex thin film and helps that the ethyl group is sublimed out of the thin film. Also the post-heat-treatment has an effect of eliminating the silicon-oxide of hydrogen (Si—OH) bond existing in the thin film.

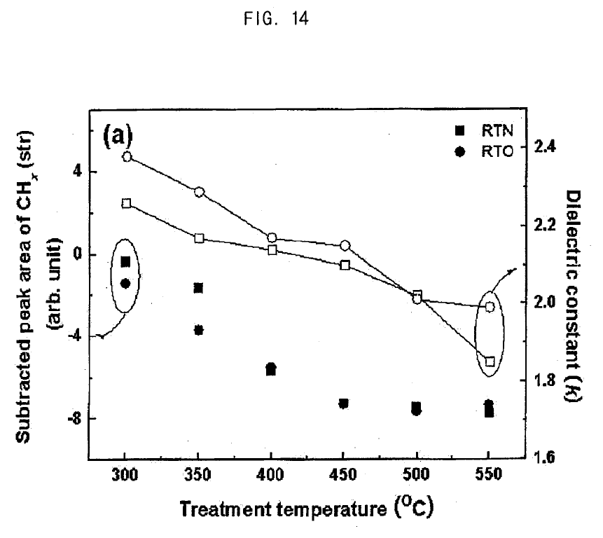

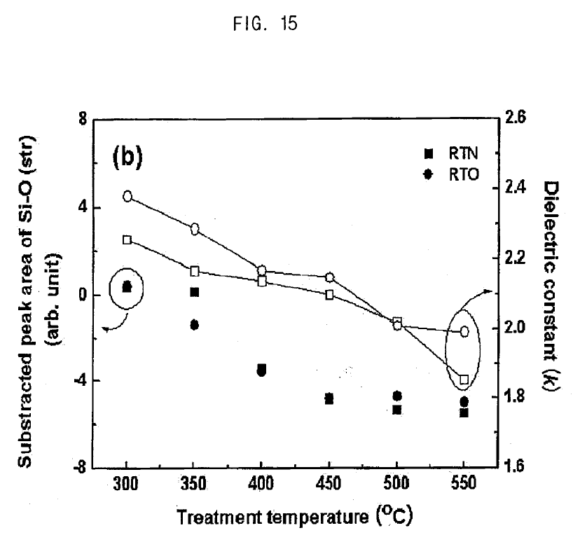

FIG. 14 illustrates a variation of a dielectric constant according to the amount of hydrocarbon (CHₓ) existing in the thin film. Because an organic matters in the early plasma-deposited PPDMCPSO:CHex thin film are sublimed to the outside according to the increased temperature, the hydrocarbons in the thin film is decreased and dielectric constant of the thin film is also decreased. Also, FIG. 15 illustrates a variation of a dielectric constant according to the amount of silicon-related bond existing in the thin film. The silicon-related chemical bonds are carbon-silicon oxide (C—SiO), oxygen-silicon oxide (O—SiO) and silicon-methyl (Si—CH₃), and the amount of silicon-related bonds are decreased. Referring to FIGS. 14 and 15, the amount of silicon-related bonds of FIG. 15 is less decreased than that of hydrocarbon bonds of FIG. 14. Namely, the decrease of dielectric constant is related to the decrease of hydrocarbon.

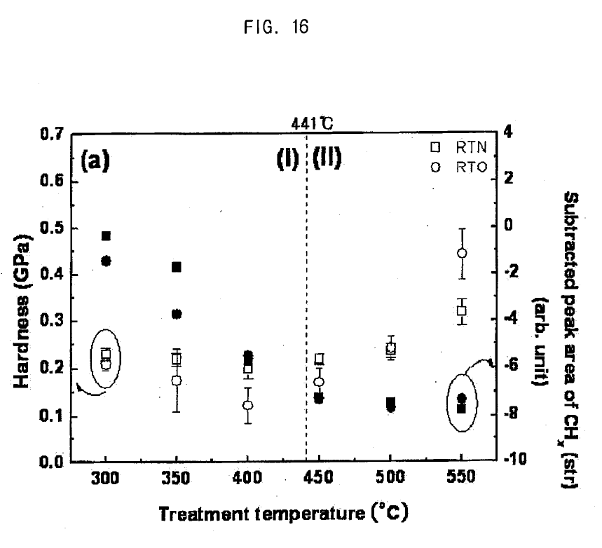

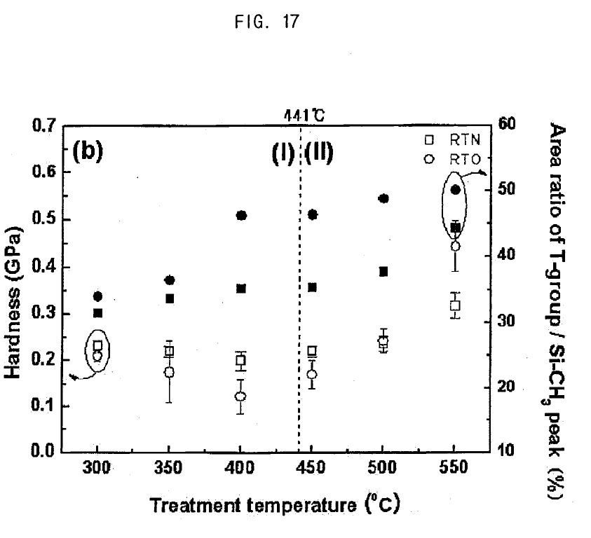

FIG. 16 illustrates a variation of hardness of the thin film according to the effect of amount of hydrocarbon (CHₓ). If 441° C. is established as a standard, the amount of hydrocarbon in the thin film and the hardness of the thin film in area I is decreased as the temperature is increased. The hardness of the thin film is considered weaker because holes are formed in the position at which hydrocarbon is sublimed to the outside. In area II, the structure of the thin film is changed as the temperature is increased. FIG. 17 illustrates a variation of hardness of the thin film according to the relative amount of oxygen-silicon-methyl (O₃—Si—(CH₃)₁) against silicon-methyl (Si—CH₃) in the post-heated thin film by using O₂ (RTO). According to the increase of ratio of oxygen-silicon-methyl in the thin film, the hardness of the thin film is over three times harder due to the change in the thin film structure. The hardness of the thin film is increased due to the large number of oxygen-silicon bonds in the thin film.

According to the result of measured reliability, the thin film, which is the heat-treated PPDMCPSO:CHex thin film that is polymerized by a plasma-enhanced CVD (PECVD) process using cyclopentasiloxane and cyclohexane precursors, shows superior qualities in the dielectric property, variation in the thickness of the thin film, variation in the chemical bonding structure, hardness and elastic modulus.

According to the present invention, the low-k thin film, which has exceptionally low dielectric constant over the prior art, can be manufactured by additionally post-heat treating a plasma-polymerized polymeric thin film deposited by the PECVD process using cyclic-shaped precursors. Moreover, according to the present invention, the thin film, which is manufactured by the above mentioned process, can form pores not exceeding the size of several nm and shorten the complicated process and the period of time for pre- and post-treatments in the spin casting process. Furthermore, the process according to the present invention can improve a dielectric constant and mechanical properties.

While specific embodiments of the invention have been described in detail, it will be appreciated by those skilled in the art that various modifications and alternatives to those details could be developed in light of the overall teachings of the disclosure. Accordingly, the particular arrangements disclosed are meant to be illustrative only and not limiting as to the scope of the invention which is to be given the full breadth of the appended claims and any equivalent thereof.

What is claimed is:

1. A method of manufacturing a low-k thin film, the method comprising:
depositing a plasma-polymerized thin film on a substrate using decamethylcyclopentasiloxane and cyclohexane precursors by plasma-enhanced CVD (PECVD); and
post-heat-treating by an RTA device.

2. The method of claim 1, wherein the post-heat-treating by the RTA device comprises heat-treating by using N₂ or O₂.

3. A method of manufacturing a low-k thin film, the method comprising:
evaporating a precursor solution comprising decamethyl-cyclopentasiloxane and cyclohexane in a bubbler;
inflowing the evaporated precursor from the bubbler to a plasma deposition reactor;
depositing a plasma-polymerized thin film on a substrate in the reactor by using a plasma in the reactor; and
post-heat-treating by an RTA device.

4. The method of claim 3, wherein the post-heat-treating by the RTA device comprises placing the substrate in an RTA chamber and heating the substrate by using several halogen lamps positioned in the RTA chamber.

5. The method of claim 3, wherein the post-heat treating by the RTA device comprises heat treating by using N₂ or O₂.

6. The method of claim 4, wherein the post-heat treating by the RTA device is executed at a temperature between 300° C. and 600° C. for 1 to 5 minutes.

7. The method of claim 4, wherein the post-heat treating by the RTA device is executed at a pressure between 0.5 atm and 1.5 atm.

8. The method of claim 3, wherein the pressure of a carrier gas in the reactor is between 10×10⁻¹ and 15×10⁻¹ Torr, and the temperature of the substrate is between 20° C. and 35° C., and electric power supplied from the reactor is between 10 W and 20 W, and a plasma frequency made therefrom is 13.56 MHz.

9. A thin film manufactured by:
depositing a plasma-polymerized thin film on a substrate using decamethylcyclopentasiloxane and cyclohexane precursors by plasma-enhanced CVD (PECVD); and
post-heat-treating the thin film by an RTA device.

10. The thin film of claim 9 wherein the post-heat-treating by the RTA device comprises heat-treating by using N₂ or O₂.

11. A thin film manufactured by:
evaporating a precursor solution comprising decamethyl-cyclopentasiloxane and cyclohexane in a bubbler;
inflowing the evaporated precursor from the bubbler to a plasma deposition reactor;
depositing a plasma-polymerized thin film on a substrate in the reactor by using a plasma in the reactor; and
post-heat-treating the thin film by an RTA device.

12. The thin film of claim 11, wherein the post-heat-treating by the RTA device comprises placing the substrate in an RTA chamber and heating the substrate by using several halogen lamps positioned in the RTA chamber.

13. The thin film of claim 11, wherein the post-heat treating by the RTA device comprises heat treating by using N₂ or O₂.

14. The thin film of claim 12, wherein the post-heat treating by the RTA device is executed at a temperature between 300° C. and 600° C. for 1 to 5 minutes.

15. The thin film of claim 12, wherein the post-heat treating by the RTA device is executed at a pressure between 0.5 atm and 1.5 atm.

16. The thin film of claim 11, wherein the pressure of a carrier gas in the reactor is between 10×10⁻¹ and 15×10⁻¹ Torr and the temperature of the substrate is between 20° C. and 35° C., and electric power supplied from the reactor is between 10 W and 20 W, and a plasma frequency made therefrom is 13.56 MHz.
